(19) United States
(12) Patent Application Publication
(10) Pub. No.: US 2024/0281570 A1
(43) Pub. Date: Aug. 22, 2024

(54) THERMO-MECHANICAL LOADS IN STRUCTURAL FASTENED JOINTS

(71) Applicant: The Boeing Company, Arlington, VA (US)

(72) Inventors: Bryan Williams Lilley, Austin, TX (US); Joseph Daniel Schaefer, Richmond Heights, MO (US); Matthew J. Molitor, O'Fallon, MO (US)

(21) Appl. No.: 18/444,115

(22) Filed: Feb. 16, 2024

Related U.S. Application Data
(60) Provisional application No. 63/486,239, filed on Feb. 21, 2023.

(51) Int. Cl. G06F 30/17; G01M 5/00; G01N 3/24

(52) U.S. Cl. CPC G06F 30/17; G01M 5/005; G01N 3/24; G01N 2203/0025; G01N 2203/0075

(57) ABSTRACT

Methods of designing a structure taking into account thermal loads are presented. A method to analyze thermal build-up in a joint is presented. Physical testing between a first material and a second material is performed to determine physical data comprising at least one of stiffness, strain, load, and displacement. The physical data is analyzed. A closed form equation is generated based on the analysis to calculate the thermal build-up in the joint.

### CROSS-REFERENCE TO RELATED APPLICATION

This application claims the benefit of U.S. Provisional Patent Application Ser. No. 63/486,239, filed Feb. 21, 2023, and entitled “Thermo-Mechanical Loads in Structural Fastened Joints,” which is incorporated herein by reference in its entirety.

### BACKGROUND INFORMATION

### 1. Field

The present disclosure relates generally to analysis and design of structures and more particularly to the loads in structural fastened joints in structures.

### 2. Background

Aircraft and other large vehicles include numerous different types of materials and components. In some large vehicles, dissimilar materials, such as metals and composites, are joined together. Dissimilar materials can have different coefficients of thermal expansion. At joints between two materials of dissimilar properties, a differential strain results as each material will expand or contract proportionally to its respective coefficient of thermal expansion. A differential strain can result when one material expands or contracts more than the other at a given temperature.

Modeling thermal loads in designing large vehicles can be undesirable difficult or undesirably time-consuming. Modeling the thermal loads can be complicated by at least one of material choice, joint size, and component quantities in the structural application/configuration.

Therefore, it would be desirable to have a method and apparatus that takes into account at least some of the issues discussed above, as well as other possible issues.

### SUMMARY

An embodiment of the present disclosure provides a method of designing a structure based on joint behaviors. A number of physical tests is performed of a single shear joint having a first component of a first material and a second component of a second material to define joint parameters. A number of physical tests is performed using a single row joint testing equipment with a plurality of fasteners joining a first longitudinal component formed of the first material and a second longitudinal component formed of the second material to define strain data. A load state equation is generated for determining a load for a joint between the first material and the second material using the joint parameters and the strain data.

Another embodiment of the present disclosure provides a method for verifying loads on a structure based on joint behaviors. Joint parameters and strain data are received from single fastener testing and multiple fastener testing having a same interface condition, same materials, and same fastener effects as a joint of the structure under design. A load for the joint is determined using the joint parameters and strain data. A model of the design for the structure is modified based on the load.

Yet another embodiment of the present disclosure provides a method to analyze thermal build-up in a joint. Physical testing is performed between a first material and a second material to determine physical data comprising at least one of stiffness, strain, load, and displacement. The physical data is analyzed. A closed form equation is generated based on the analysis to calculate the thermal build-up in the joint.

A further embodiment of the present disclosure provides a method of determining a stiffness of a joint. A single shear joint with a first component of a first material and a second component of a second material is assembled. Single shear testing is performed on the single shear joint at a plurality of temperatures to generate physical data. The physical data is analyzed to determine a relationship between temperature change and in-plane stiffness.

A yet further embodiment of the present disclosure provides a method of designing a structure based on joint behaviors. A plurality of fasteners is installed through a first longitudinal component and second longitudinal component such that the plurality of fasteners are linearly arranged along a length of the first longitudinal component to form single row joint testing equipment, the single row joint testing equipment having materials in a design of a joint of the structure. Strain testing is performed on the single row joint testing equipment. Strain data is received from a number of strain gauges adhered to the first longitudinal component during strain testing of the single row joint testing equipment. Influence of interface conditions and fastener effects on the strain in the structure is determined based on the strain data.

A yet further embodiment of the present disclosure provides a single row joint testing equipment. The single row joint testing equipment comprises a first longitudinal component, a second longitudinal component, and a plurality of strain gauges. The first longitudinal component has a first testing face with a first plurality of holes extending through the first testing face and linearly arranged along a length of the first longitudinal component. The plurality of strain gauges is connected to measuring face of the first longitudinal component opposite the first testing face. The second longitudinal component with a second testing face with a second plurality of holes extending through the second testing face and linearly arranged, wherein the second plurality of holes have the same spacing and diameter as the first plurality of holes, the second testing face configured to contact the first testing face.

The features and functions can be achieved independently in various embodiments of the present disclosure or may be combined in yet other embodiments in which further details can be seen with reference to the following description and drawings.

### BRIEF DESCRIPTION OF THE DRAWINGS

The novel features believed characteristic of the illustrative embodiments are set forth in the appended claims. The illustrative embodiments, however, as well as a preferred mode of use, further objectives and features thereof, will best be understood by reference to the following detailed description of an illustrative embodiment of the present disclosure when read in conjunction with the accompanying drawings, wherein:

FIG. 1 is an illustration of an aircraft in accordance with an illustrative embodiment;

FIG. 2 is an illustration of a block diagram of a design environment in accordance with an illustrative embodiment;

FIG. 3 is an illustration of an isometric view of a single shear joint in accordance with an illustrative embodiment;

FIG. 4 is an illustration of an exploded view of single row joint testing equipment in accordance with an illustrative embodiment;

FIG. 5 is an illustration of a top view of Single row joint testing equipment in accordance with an illustrative embodiment;

FIG. 6 is an illustration of a front view of Single row joint testing equipment in accordance with an illustrative embodiment;

FIG. 7 is an illustration of a front view of Single row joint testing equipment in accordance with an illustrative embodiment;

FIG. 8 is an illustration of a front view of Single row joint testing equipment in accordance with an illustrative embodiment;

FIG. 9 is a flowchart of a method of designing a structure based on joint behaviors in accordance with an illustrative embodiment;

FIG. 10 is a flowchart of a method of designing a structure based on joint behaviors in accordance with an illustrative embodiment;

FIG. 11 is a flowchart of a method of analyzing thermal build-up in a joint is depicted in accordance with an illustrative embodiment.

FIG. 12 is a flowchart of a method of determining a stiffness of a joint is depicted in accordance with an illustrative embodiment.

FIGS. 13A and 13B are a flowchart of a method of designing a structure based on joint behaviors is depicted in accordance with an illustrative embodiment;

FIG. 14 is an illustration of an aircraft manufacturing and service method in a form of a block diagram is depicted in accordance with an illustrative embodiment; and

FIG. 15 is an illustration of an aircraft in a form of a block diagram in which an illustrative embodiment may be implemented.

### DETAILED DESCRIPTION

The illustrative examples recognize and take into account one or more different considerations. For example, the illustrative examples recognize and take into account that in vehicle analysis and design, thermally induced stresses may not be modeled in structural fastened joints with disparate materials.

Disparate materials can be used in joints. For example, some joints in aircraft and other vehicles include metal-to-composite joints. The illustrative examples recognize and take into account that currently loads models for thermal and mechanical response are not used at the vehicle level.

The illustrative examples recognize and take into account that elevated safety factors are incorporated into the structural design when thermal loads are not taken into account. The illustrative examples recognize and take into account that higher safety factors for structural design result in higher structural weight, reduced payload, and reduced fuel efficiency. Design of structures without loads models utilizes undesirably high human/person-hours to perform fail-safe loads analysis. Increased person-hours can undesirably increase program cost and delay design schedule.

The illustrative examples recognize and take into account that the ability of the materials to expand or contract (strain) is restricted by the fasteners between the joined members. The illustrative examples recognize and take into account that the legacy industry approach uses a vehicle finite element model (FEM) consisting of large shell elements tied together by rigid connection across fastened regions. The illustrative examples recognize and take into account that an assumption of an infinitely rigid fastener significantly affects the resulting stress in the members.

The illustrative examples use fundamentally improve fastened joint analysis with strategically obtained test data to calibrate clamp-up responses and in-plane stiffness to rapidly provide corrections to the standard approach of thermal loads analysis in structural fastened joints. The illustrative examples provide test data from two different tests—single shear testing and a multiple fastener test—that will be analyzed. After analyzing the test data, a closed form equation is developed to calculate the thermal build-up in a joint.

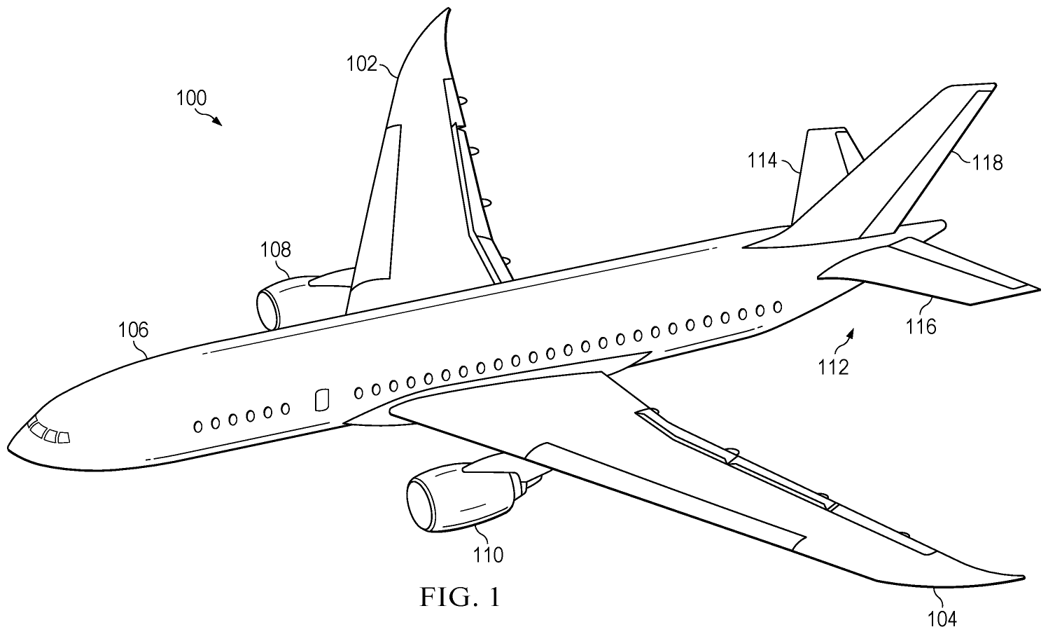

Turning now to FIG. 1, an illustration of an aircraft is depicted in accordance with an illustrative embodiment. Aircraft 100 has wing 102 and wing 104 attached to body 106. Aircraft 100 includes engine 108 attached to wing 102 and engine 110 attached to wing 104.

Body 106 has tail section 112. Horizontal stabilizer 114, horizontal stabilizer 116, and vertical stabilizer 118 are attached to tail section 112 of body 106.

Aircraft 100 is an example of an aircraft that can be designed using the methods and single row joint testing equipment of the illustrative examples. Joints in at least one of body 106, wing 102, or wing 104 can be modeled using joint parameters of at least one of single fastener testing or multiple fastener testing of the illustrative examples. Loads in a joint in at least one of body 106, wing 102, or wing 104 can be modeled using the load state equation of the illustrative examples.

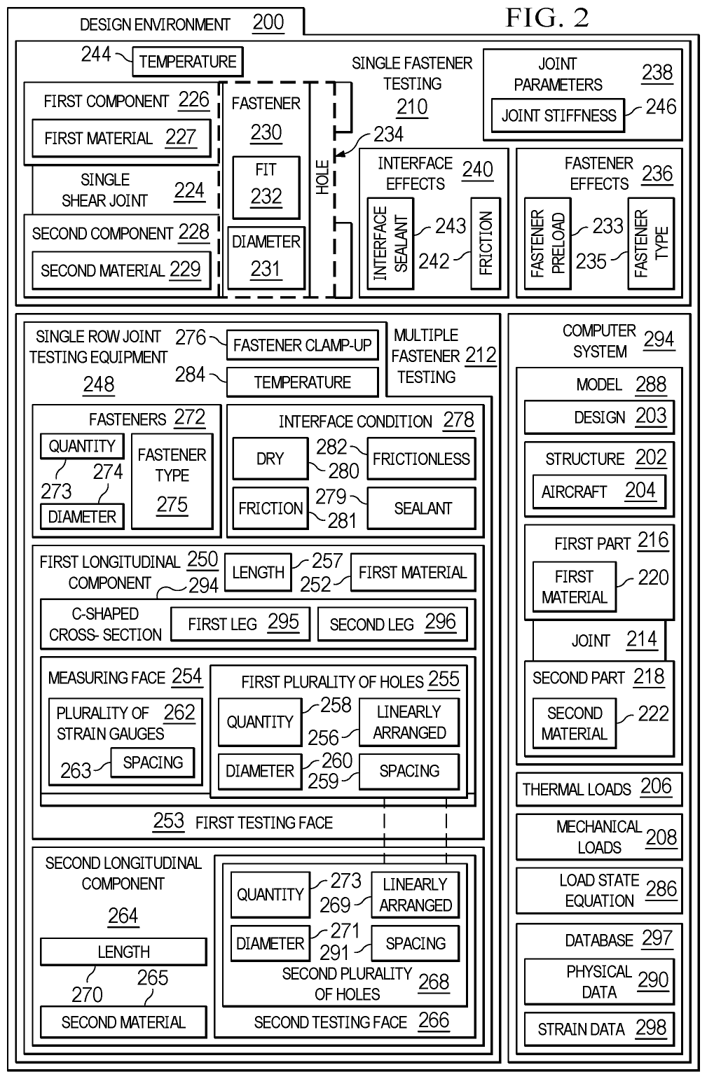

Turning now to FIG. 2, an illustration of a block diagram of a design environment is depicted in accordance with an illustrative embodiment. Design environment 200 is an environment for designing structure 202. In some illustrative examples, structure 202 takes the form of aircraft 204. Structure 202 goes through several iterations of design and testing. Aircraft 204 can be a design of aircraft 100 of FIG. 1.

In some illustrative examples, to take into account thermal loads 206 and mechanical loads 208 in designing structure 202, at least one of single fastener testing 210 or multiple fastener testing 212 is performed.

Single fastener testing 210 comprises a number of physical tests of single shear joint 224. Multiple fastener testing 212 comprises a number of physical tests using single row joint testing equipment 248.

Structure 202 comprises joint 214 between first part 216 and second part 218. First part 216 can also be referred to as a first component. Second part 218 can also be referred to as a second component. First part 216 and second part 218 are components of a structure. First part 216 is formed of first material 220 and second part 218 is formed of second material 222. First material 220 and second material 222 can be any desirable materials. In some illustrative examples, first material 220 and second material 222 can be dissimilar materials. In some illustrative examples, first material 220 and second material 222 can have dissimilar thermal coefficients. In some illustrative examples, first material 220 and second material 222 can have at least one of different modulus, different stiffness, different strengths, or other different material behaviors.

First material 220 and second material 222 can be formed into first component 226 and second component 228 in any desirable method. In some illustrative examples, at least one of milling, molding, additive manufacturing, or any other desirable method.

In some illustrative examples, first material 220 is a metal. In some illustrative examples, first material 220 is a composite material. In some illustrative examples, second material 222 is a composite material formed of a fiber reinforced resin.

In some illustrative examples, single fastener testing 210 is performed on single shear joint 224 formed of the same materials as joint 214. In some illustrative examples, single fastener testing 210 can be referred to as strain testing on single shear joint 224. Single shear joint 224 is formed by joining first component 226 and second component 228 by fastener 230. First component 226 comprises first material 227. Second component 228 comprises second material 229.

Fastener 230 extends through hole 234. Properties of fastener 230 can be modified to determine fastener effects 236 to joint parameters 238. Fastener effects 236 include effects of fit 232 of fastener 230 in hole 234, diameter 231 of fastener 230, fastener preload 233, and fastener type 235. Fastener preload 233 can also be referred to as clamping in single shear joint 224. Fastener type 235 has effects on joint parameters 238 due to material properties and other characteristic of fastener 230. For example, fastener 230 is formed of a material with stiffness, strength, and other material properties. Fastener 230 can be held in place by a nut and in some illustrative examples includes a washer. Fastener type 235 can be of any form. In some illustrative examples, fastener type 235 includes a protruding head or a countersunk head.

Other aspects of single shear joint 224 are evaluated to determine interface effects 240 on joint parameters 238. In some illustrative examples, interface effects 240 includes whether the interface between fastener 230 and hole 234 includes friction 242 or is frictionless. In some illustrative examples, interface effects 240 includes whether the interface is dry or includes interface sealant 243.

Interface effects 240 can refer to an interface between fastener 230 and hole 234. Interface effects 240 can also refer to an interface between first component 226 and second component 228. Friction 242 could be in the form of interference to the fit of the fastener itself within hole 234 through the material. Friction 242 can describe the friction between the two materials, first material 227 and second material 229, being compressed by virtue of fastener 230 being present. All of the above are parameters driving joint stiffness 246 or ‘compliance’ which is also affected by thermal and mechanical loads.

By modifying aspects of fastener 230, fastener effects 236 to joint parameters 238 are determined. By modifying aspects of the interface between fastener 230 and hole 234, interface effects 240 to joint parameters 238 are determined.

Additionally, temperature 244 can be changed during testing of single shear joint 224. Temperature 244 can be adjusted to determine thermal loads in single shear joint 224. By running single fastener testing 210 at multiple values of temperature 244, joint stiffness 246 at the different values of temperature 244 is determined. An analysis of the physical results of single fastener testing 210 can determine a relationship between joint stiffness 246 and temperature 244. In some illustrative examples, performing strain testing, single fastener testing 210, on single row joint testing equipment 248 comprises performing strain testing on single row joint testing equipment 248 at a plurality of temperatures 244. In some illustrative examples, thermal effects are determined on the strain of single row joint testing equipment 248 using data from the strain testing, single fastener testing 210, at the plurality of temperatures 244.

In some illustrative examples, after performing single fastener testing 210, multiple fastener testing 212 is performed. Multiple fastener testing 212 can be used to validate joint stiffness 246 of single fastener testing 210. Multiple fastener testing 212 is performed to characterize and quantify effects of thermal strain development in joints of different lengths. In some illustrative examples, multiple fastener testing 212 is used to update joint parameters 238 based on a quantity of fasteners in joint 214 of structure 202. In some illustrative examples, multiple fastener testing 212 is used to update joint parameters 238 based on a desired length of joint 214 in structure 202.

Multiple fastener testing 212 is performed using single row joint testing equipment 248. In some illustrative examples, multiple fastener testing 212 can be referred to as strain testing on single row testing equipment 248. Single row joint testing equipment 248 is configured to test how thermal loads build up along a length of a fastener pattern. Single row joint testing equipment 248 is configured to test how thermal loads build up along a length of a fastener pattern.

In some illustrative examples, single row joint testing equipment 248 comprises first longitudinal component 250, plurality of strain gauges 262, and second longitudinal component 264. Although plurality of strain gauges 262 is discussed here, any desirable type of sensors can be attached to single row joint testing equipment 248. In some illustrative examples, additional or different sensors to characterize strain and/or displacement are present. Additional sensors can include digital image correlation, extensometers, Moiré, or other types of sensors. First longitudinal component 250 is formed of first material 252. In some illustrative examples, first material 252 is the same as first material 220 of first part 216 in model 288. In some illustrative examples, first material 252 is a material for a stiffener of structure 202. In some illustrative examples, single fastener testing 210 is performed prior to multiple fastener testing 212 and first material 252 is the same as first material 227.

First longitudinal component 250 has first testing face 253 with first plurality of holes 255 extending through first testing face 253 and linearly arranged 256 along length 257 of first longitudinal component 250. First plurality of holes 255 has quantity 258, spacing 259, and diameter 260 based on a design for structure 202. First plurality of holes 255 is a set of pre-drilled fastener locations. Diameter 260 is set based on diameter 274 of fasteners 272 to be used. In some illustrative examples, spacing 259 is set based on standard spacing for diameter 274 of fasteners 272. First plurality of holes 255 can be designed based on at least one of fastener type 275, diameter 274 of fasteners 272, and design of joint 214. In some illustrative examples, spacing 259 is set based on relevant structural or design criteria and/or guidelines for at least one of structure 202, first material 220, second material 222, or joint 214.

In some illustrative examples, first plurality of holes 255 comprises more than one diameter of hole. First plurality of holes 255 are drilled through first longitudinal component 250 such that first plurality of holes 255 extend through both first testing face 253 and measuring face 254 of first longitudinal component 250.

In some illustrative examples, first longitudinal component 250 has C-shaped cross-section 294. When present, C-shaped cross-section 294 can reduce or eliminate first longitudinal component 250 bending out of plane due to stress build-up during testing. In some illustrative examples, C-shaped cross-section 294 is formed by first leg 295 extending perpendicular to first testing face 253 and second leg 296 extending perpendicular to first testing face 253. In some illustrative examples, first leg 295 and second leg 296 each extend outwardly from measuring face 254 to form C-shaped cross-section 294.

Although C-shaped cross-section 294 is discussed, in some illustrative examples, first longitudinal component 250 can have a different cross-sectional shape. In some illustrative examples, first longitudinal component 250 has another desirable cross-sectional shape configured to provide a stable and balanced test article substantially free of unwanted attributes/artifacts.

A plurality of sensors is connected to measuring face 254 of first longitudinal component 250. The plurality of sensors can take any desirable form. The plurality of sensors provides surface inspection with a desired fidelity and resolution to measure desired displacement or strain attributes. In some illustrative examples, the plurality of sensors takes the form of plurality of strain gauges 262. Plurality of strain gauges 262 is connected to measuring face 254 of first longitudinal component 250 opposite first testing face 253. In some illustrative examples, plurality of strain gauges 262 is positioned between holes of first plurality of holes 255. In some illustrative examples, plurality of strain gauges 262 is positioned such that spacing 263 between plurality of strain gauges 262 is unequal. In some illustrative examples, spacing 263 between plurality of strain gauges 262 increases along length 257 of first longitudinal component 250.

Second longitudinal component 264 is formed of second material 265. In some illustrative examples, second material 265 is the same as second material 222 of second part 218 in model 288. In some illustrative examples, second material 265 is a material for a skin of structure 202. Single fastener testing 210 is performed prior to multiple fastener testing 212 and second material 265 is the same as second material 229.

In some illustrative examples, materials for first longitudinal component 250 and second longitudinal component 264 are selected based on materials for aircraft 204. In some illustrative examples, first material 252 and second material 265 are selected based on first material 220 and second material 222 for aircraft 204.

Second longitudinal component 264 has any desirable cross-sectional shape. In some illustrative examples, second longitudinal component 264 is a plate.

Second longitudinal component 264 has second testing face 266 with second plurality of holes 268 extending through second testing face 266 and linearly arranged 269 along length 270. Second plurality of holes 268 has quantity 273, spacing 291, and diameter 271. Second plurality of holes 268 has the same spacing and diameter as first plurality of holes 255. Accordingly, spacing 291 is the same as spacing 259 and diameter 271 is the same as diameter 260. Second testing face 266 is configured to contact first testing face 253.

To perform multiple fastener testing 212, fasteners 272 are installed through first plurality of holes 255 and second plurality of holes 268. Fasteners 272 join first longitudinal component 250 and second longitudinal component 264 with first testing face 253 in contact with second testing face 266. Any desirable quantity 273 of fasteners 272 can be installed through first plurality of holes 255 and second plurality of holes 268. In some illustrative examples, quantity 273 of fasteners 272 is the same as quantity 258 of first plurality of holes 255 and quantity 273 of second plurality of holes 268. In some illustrative examples, quantity 273 of fasteners 272 is less than quantity 258 of first plurality of holes 255 and quantity 273 of second plurality of holes 268.

Single row joint testing equipment 248 is designed to allow for adapting multiple fastener testing 212 to different characteristics for interface condition 278 and fastener clamp-up 276. Interface condition 278 includes at least one of sealant 279 or dry 280, and friction 281 or frictionless 282.

Sealant 279 can be used to surround a respective fastener of fasteners 272 within a respective hole. Sealant 279 can be used between the materials being joined, first longitudinal component 250 and second longitudinal component 264. An interface can be between a fastener of fasteners 272 and first longitudinal component 250 and second longitudinal component 264. An interface can be between first longitudinal component 250 and second longitudinal component 264. In some illustrative examples, sealant 279 is not used in a respective interface and that respective interface is dry 280.

Single row joint testing equipment 248 is manufactured and modified to test conditions for joint 214. Interface condition 278 and fastener clamp-up 276 can be modified without modifying the geometry of first longitudinal component 250 or second longitudinal component 264. In some illustrative examples, fasteners with different characteristics, such as a different fastener type 275 or a different diameter 274 of fasteners 272, can be tested using additional longitudinal components. For example, fasteners with a different diameter than diameter 274 can be used in a single row joint testing equipment with longitudinal components with holes with different diameters than diameter 260 and diameter 271.

Single row joint testing equipment 248 provides the ability to characterize and quantity the effects of thermal strain development during environmental testing of joints of different lengths. Single row joint testing equipment 248 provides the ability to replicate any quantity of different joint conditions and sizes with one test article. By adding different quantities of fasteners 272 to first plurality of holes 255 and second plurality of holes 268, joints of different lengths are created. By adjusting the quantity of fasteners inserted into the joint, the effective length of the fastened joint between first longitudinal component 250 and second longitudinal component 264 can be controlled.

By running multiple tests on single row joint testing equipment 248 with different quantities of fasteners 272 and changing temperature 284, physical data 290, including strain data 298, is collected for the design of joint 214. Strain data 298 can be stored in database 297. Database 297 stores physical data 290 from single fastener testing 210 and multiple fastener testing 212. In some illustrative examples, database 297 includes information regarding first material 227, second material 229, interface effects 240, fastener effects 236, as well as sensor data from testing single shear joint 224. In some illustrative examples, joint parameters 238, including joint stiffness 246, are stored in database 297. In some illustrative examples, database 297 includes information regarding first material 252, second material 265, fasteners 272, and interface condition 278, as well as sensor data from testing using single row joint testing equipment 248. In some illustrative examples, physical data 290 includes strain data 298.

Influences of interface condition 278, fastener clamp-up 276, fastener type 275, diameter 274 of fasteners 272, and other aspects of joint 214 on stresses and loads can be investigated through multiple fastener testing 212. After receiving physical data 290 from single fastener testing 210 and multiple fastener testing 212, relationships are determined between the thermal loads, fastener effects, and interface effects. During analysis of physical data 290, physical data 290 is phenomenologically analyzed to determine mathematical relationships to model this data.

In some illustrative examples, after performing modeling, a user subroutine can be created to describe joint stiffness 246 as a function of parameters of single shear joint 224.

Either physical test results, strain data 298, from single fastener testing 210 and multiple fastener testing 212 or thermal analysis using smaller representative sprung models can be used to develop a closed form equation of a logistic function form to describe the stress and/or load state of single row joint testing equipment 248 over all possible joint lengths well. This function can in turn be used to find the bearing loads in the fasteners of joint 214. Design curves can be developed as part of the method for any given combination of materials to be fastened and subjected to thermal loads. One closed form solution can have the following form:—

$$P ( x ; x ∈ [ 0 , \frac{L}{2} ] ) = K ( \frac{2}{1 + {e}^{- B x}} - 1 )$$

K is the “carrying capacity” equal to the upper limit of load in joint 214. May be defined by the test or sprung model for specific joint build-up. B is the growth rate. The growth rate is the rate at which the load reaches the carrying capacity. The growth rate, B, is affected by the in-plane stiffness variables: interface effects 240, joint materials, first material 252 and second material 265, fastener clamp-up 276, fastener fit, fastener material, fastener spacing, spacing 259. X is a lengthwise position. X is a dependent variable symmetric about center of a symmetric joint of length L.

When physical data 290 from single fastener testing 210 and multiple fastener testing 212 is used, strain data 298 is utilized in growth rate, B. Growth rate B is one way of incorporating material effects into the closed form equation.

In some illustrative examples, the closed form equation can be referred to as load state equation 286. In some illustrative examples, generating load state equation 286 comprises analyzing joint parameters 238 and strain data 298 to determine a correlation for joint parameters 238 and strain data 298 and expressing the correlation in a closed form equation taking into account fastener effects 236 and interface effects 240.

Either analytical or physical approaches for single fastener testing 210 and multiple fastener testing 212 in combination provide information to describe the accurate state of stress and load in a fastened joint subjected to thermal strains that has been shown to be less than or equal to the output of a welded FEM.

A theoretical model can be built to match the test data output from the single row joint testing equipment 248. The theoretical data model can take any desirable form. In some illustrative examples, a sprung FEM model can be used. A sprung FEM model can be created by using the data from single fastener testing 210 to define a user-subroutine which describes the individual fastener stiffness as a function of thermal and mechanical loading (thermo-mechanical) and including other aspects of joint compliance/response. This sprung FEM model describes joint parameters 238. Afterwards, the user-subroutine for the fastener stiffness is assigned to define a surface to surface contact relationship between the finite elements of two materials, or the behavior of an element embedded within two materials to represent the fastener, or an analytical fastener geometry within the model.

After determining a closed form equation, the equation can be used to determine a thermal load for joint 214. This closed form equation can be used separately from a standard design model process and then used to compare to estimated loads in the design model process to the determined load from the closed form equation. In some illustrative examples, the closed form equation can be implemented within the design model process instead of undesirably conservative safety factors.

Implementation of the illustrative examples then provides a means for analysts to readily use output from a standard vehicle level FEM and find the appropriate knockdown using the informed closed form function for the given materials as a means to create thermo-mechanical design curves which are used to reduce conservatism and reduce weight in the vehicle, structure 202.

The illustrative examples provide an ability to generate a closed form description of the stress state and bearing loads in a vehicle, structure 202, that can be used to create thermo-mechanical design curves as a parameterized function by a stress analyst to correct load output from the welded FEM. The illustrative examples can replace undesirably high safety factor applications which lead to unnecessary increased member sizes and weight.

In the illustrative examples, a theoretical model can be made to the single shear data from single fastener testing 210 to provide a model for joint stiffness 246 as a function of temperature 244 and/or mechanical loading (thermo-mechanical). The theoretical model can be developed based on first principles, such as material properties, joint design attributes such as fastener clamp-up 276, fastener size, material thicknesses/geometries, and any other parameters. The theoretical model can be developed based on a polynomial or any other applicable equation form applied to the data. In these illustrative examples, the theoretical model may be developed on the polynomial and will not rely on first principles or science.

The theoretical model can be coded into a user-subroutine for finite element analysis. The finite element analysis can assign the user-subroutine as a material behavior for a ‘sprung’ fastener model (actual part representing a fastener) holding two surfaces/materials/parts/structures/etc. (a first and second entity) together. The finite element analysis can assign the user-subroutine as a contact condition between two surfaces/materials/parts/structures/etc. The finite element analysis can assign the user-subroutine as a material behavior for an embedded element within the above to represent a fastener/fastened condition. The above behaviors can be linear, nonlinear, or any combination thereof.

The single fastener condition defined by the single shear data from single fastener testing 210 can be used within a finite element analysis to create an output data/response which is then fit with a new theory (first-principles) and/or polynomial (phenomenological relationship) to create a closed form solution defining a design space. The design space would provide those skilled in the state of the art to parametrically design new joints for relevant mechanical and thermal conditions with lower conservatism due to an improved estimate of the contribution of thermal stresses (or relaxation thereof) within a fastener pattern of a joint.

The data from multiple fastener testing 212 validates the preceding capability. The result is a predictive finite element based sprung model applicable for all levels of structural analysis from coarse vehicle level down to high fidelity of a local analysis.

The data generated in multiple fastener testing 212 using single row joint testing equipment 248 may also be separately developed to create direct closed form solutions for specific parameters of interest, such as fastener spacing, fastener clamp-up, material types, material thicknesses/geometries, or other parameters of the joint associated with thermal building up joints. This would create closed form relationships (theory/models) for specific patterns resulting in non-predictive but still useful design info.

Model 288 is of a design for a structure comprising first part 216 and second part 218. In some illustrative examples, model 288 of the design for the structure is modified based on a load determined for joint 214 using joint parameters 238 and strain data 298. The structure is part of structure 202. In some illustrative examples, the structure is part of aircraft 204. In some illustrative examples, modifying model 288 comprises at least one of reducing a thickness of a component of the structure to reduce a weight of the structure, changing a quantity of fasteners in joint 214 of the structure, changing a type of fasteners in joint 214 of the structure, or changing a spacing of fasteners in joint 214 of the structure.

The illustration of design environment 200 in FIG. 2 is not meant to imply physical or architectural limitations to the manner in which an illustrative embodiment may be implemented. Other components in addition to or in place of the ones illustrated may be used. Some components may be unnecessary. Also, the blocks are presented to illustrate some functional components. One or more of these blocks may be combined, divided, or combined and divided into different blocks when implemented in an illustrative embodiment.

For example, fastener effects 236 can include other fastener properties such as fastener tolerance, fastener elasticity, or other aspects of fastener 230. In some examples, other interface properties can be altered to determine interface effects 240.

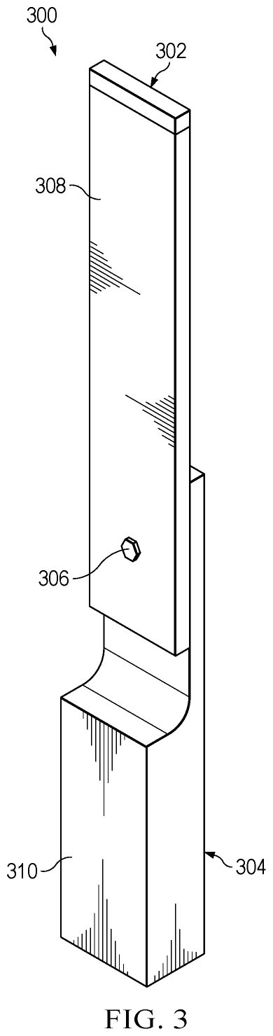

Turning now to FIG. 3, an illustration of an isometric view of a single shear joint is depicted in accordance with an illustrative embodiment. Single shear joint 300 is a physical implementation of single shear joint 224 of FIG. 2. Single shear joint 300 can be used in single fastener testing 210 of FIG. 2.

Single shear joint 300 comprises first component 302, second component 304, and fastener 306. Fastener 306 joins first component 302 to second component 304. Single shear joint 300 is formed by joining first component 302 and second component 304 by fastener 306. First component 302 comprises first material 308. Second component 304 comprises second material 310.

Fastener variables can be modified to determine fastener effects on joint parameters, such as in-plane stiffness. A type of fastener, diameter, fit, and preload of fastener 306 can be modified. In some illustrative examples, fastener variables are selected based on design. In some illustrative examples, fastener variables are selected to generate a set of data for different options and determine joint parameters for joints with different fastener variables.

The use of single shear fastened joint data generated from at least one of test or analysis is used to identify and quantify joint parameters, such as in-plane stiffness. The use of single shear fastened joint data quantifies interface effects. The interface effects are complex and the use of the interface effects improves accuracy in real-world joint behavior. The interface effects can include friction and interface sealant.

The illustrative examples provide quantitative information for thermal loads for improvements in designing structures, such as aircraft. By taking into account thermal loads, designs of structures can be modified without modifying the legacy models themselves. The illustrative examples provide temperature-dependent stiffness properties. The illustrative examples capture and quantify complex fastener/interface effects of physical joints.

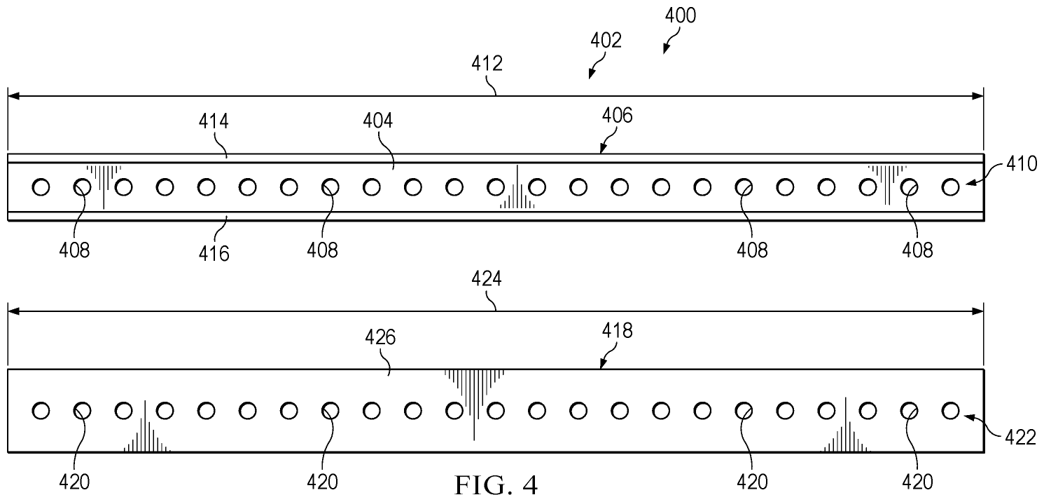

Turning now to FIG. 4, an illustration of an exploded view of single row joint testing equipment is depicted in accordance with an illustrative embodiment. Single row joint testing equipment 400 is a physical implementation of Single row joint testing equipment 248 of FIG. 2.

View 402 is a view of measuring face 404 of first longitudinal component 406 of single row joint testing equipment 400. First longitudinal component 406 comprises first plurality of holes 408 linearly arranged 410 along length 412 of first longitudinal component 406.

First longitudinal component 406 further comprises first leg 414 perpendicular to measuring face 404. First longitudinal component 406 further comprises second leg 416 perpendicular to measuring face 404. In this illustrative example, first leg 414 and second leg 416 extend from measuring face 404 out of the page in view 402.

Second longitudinal component 418 has second testing face 426 with second plurality of holes 420 extending through second testing face 426 and linearly arranged 422. Second plurality of holes 420 extend along length 424 of second longitudinal component 418. Second plurality of holes 420 have the same spacing and diameter as first plurality of holes 408. Second testing face 426 is configured to contact the first testing face (not visible). In this illustrative example, second longitudinal component 418 takes the form of a plate.

Strain data from single row joint testing equipment 400 can be used to calculate the bearing loads on fasteners in the joint. Furthermore, test results from single row joint testing equipment 400 demonstrate the effects of fastener elasticity on load in the joint and bearing loads in the fasteners relative to the loads assumed by a welded FEM.

Single row joint testing equipment 400 saves significant manufacturing cost to conduct thermal testing on elastic fastened joints. Single row joint testing equipment 400 can be used to compare to assumed values of standard vehicle-level analysis approaches that include undesirably conservative estimates. Use of testing single row joint testing equipment 400 provides remaining key parameters to describe behaviors of a fastened joint not currently used a welded FEM. One parameter generated from testing includes a data driven in-plane stiffness. single row joint testing equipment 400 is readily adapted to any potential materials, fastener types, fastener clamp-up conditions, fastener sizes/hole sizes, fastener tolerances, interface conditions (sealant, dry, friction, frictionless) etc. that may be utilized together in a vehicle. Single row joint testing equipment 400 provides for analysis into in-plane stiffness, strains, and bearing loads and is straightforward to manufacture and test.

Single row joint testing equipment 400 was designed as a test joint relevant to spars or box beams within a structure. Single row joint testing equipment 400 provides the ability to characterize and quantify the effects of thermal strain development during environmental testing of joints of various lengths in a single manufactured joint. Testing of joints of various lengths is accomplished by manufacturing a long joint with pre-drilled fastener locations. By adjusting the quantity of fasteners inserted into the joint of single row joint testing equipment 400, the effective length of the fastened joint can be controlled and many tests at temperature may be conducted on the single joint, single row joint testing equipment 400, since it remains within elastic stress limits throughout testing. Strain data from these tests can be used to calculate the bearing loads on fasteners in the joint. Furthermore, these tests demonstrate the effects of fastener elasticity on load in the joint and bearing loads in the fasteners relative to the loads assumed by a welded FEM.

Single row joint testing equipment 400 is a non-limiting example of a physical implementation of single row joint testing equipment 248 of FIG. 2. Although first plurality of holes 408 is depicted as having the same diameter, in other illustrative examples, first plurality of holes 408 can comprise more than one diameter of hole.

Turning now to FIG. 5, an illustration of a top view of single row joint testing equipment is depicted in accordance with an illustrative embodiment. View 500 is a top view of Single row joint testing equipment 400 of FIG. 4.

View 500 is a top view of first longitudinal component 406 and second longitudinal component 418. Fasteners 502 extend through the first plurality of holes (not visible) in first longitudinal component 406 and the second plurality of holes (not visible) in second longitudinal component 418.

In view 500, first leg 414 of first longitudinal component 406 extends away from first testing face 504 of first longitudinal component 406. First testing face 504 is in contact with second testing face 426 of second longitudinal component 418.

In view 500, first plurality of holes 408 of FIG. 4 is aligned with second plurality of holes 420 of FIG. 4 to allow for fasteners 502 to join first longitudinal component 406 and second longitudinal component 418. In view 500 fasteners 502 extend through first plurality of holes 408 of FIG. 4 and second plurality of holes 420 of FIG. 4.

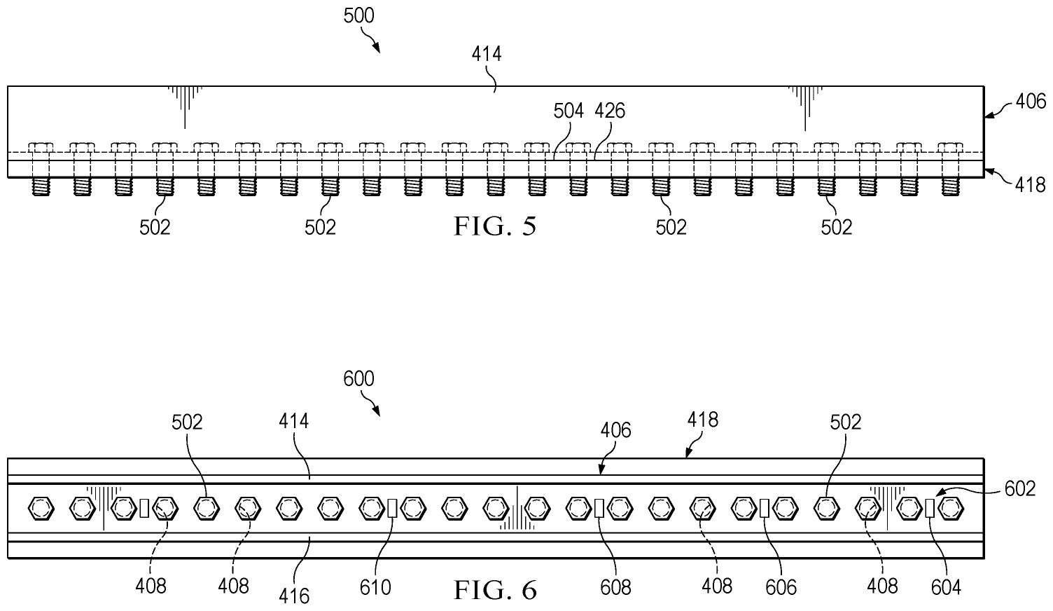

Turning now to FIG. 6, an illustration of a front view of Single row joint testing equipment is depicted in accordance with an illustrative embodiment.

Single row joint testing equipment 400 comprises first longitudinal component 406 joined to second longitudinal component 418. Single row joint testing equipment 400 comprises a first testing face (not visible) and measuring face 404 opposite the first testing face. First plurality of holes 408 extend through measuring face 404 and the first testing face. In view 600, fasteners 502 are present in each hole of first plurality of holes 408.

Plurality of strain gauges 602 is connected to measuring face 404 of first longitudinal component 406. In this illustrative example, plurality of strain gauges 602 is positioned between holes of first plurality of holes 408. In this illustrative example, plurality of strain gauges 602 is positioned such that spacing between plurality of strain gauges 602 is unequal.

In this illustrative example, the distance between strain gauge 604 and strain gauge 606 is less than the distance between strain gauge 606 and strain gauge 608. In this illustrative example, the distance between strain gauge 606 and strain gauge 608 is less than the distance between strain gauge 608 and strain gauge 610. In this illustrative example, the distance between strain gauges increases along length 412 of first longitudinal component 406.

Single row joint testing equipment 400 is subjected to a plurality of different temperatures while fasteners 502 are in place. By changing the temperature in testing single row joint testing equipment 400, the strain in single row joint testing equipment 400 due to thermal load can be determined.

Single row joint testing equipment 400 is configured to be able to alter and test temperature, time, and length of the joint. Single row joint testing equipment 400 is designed to test strain along the axis of fasteners 502. The primary strain in fasteners 502 will be along an axis parallel to length 412 of first longitudinal component 406. As described, the testing using single row joint testing equipment 400 is uniaxial. In some illustrative examples, other sensors could be utilized to characterize out of plane or normal plane behaviors.

Single row joint testing equipment 400 is configured to generate sufficient data and reduce testing costs. Although plurality of strain gauges 602 has a smaller quantity than fasteners 502, in some illustrative examples, a different quantity of sensors can be present. In some illustrative examples, a strain gauge can be present between each fastener of fasteners 502. However, price of single row joint testing equipment 400 increases with increased quantity of sensors. Further, although strain gauges are discussed, other sensors can be used in single row joint testing equipment 400. In some non-depicted examples, single row joint testing equipment 400 can have a digital image correlation. In some illustrative examples, analysis of a speckled pattern of single row joint testing equipment 400 can be performed to determine stress/strain behavior in single row joint testing equipment 400.

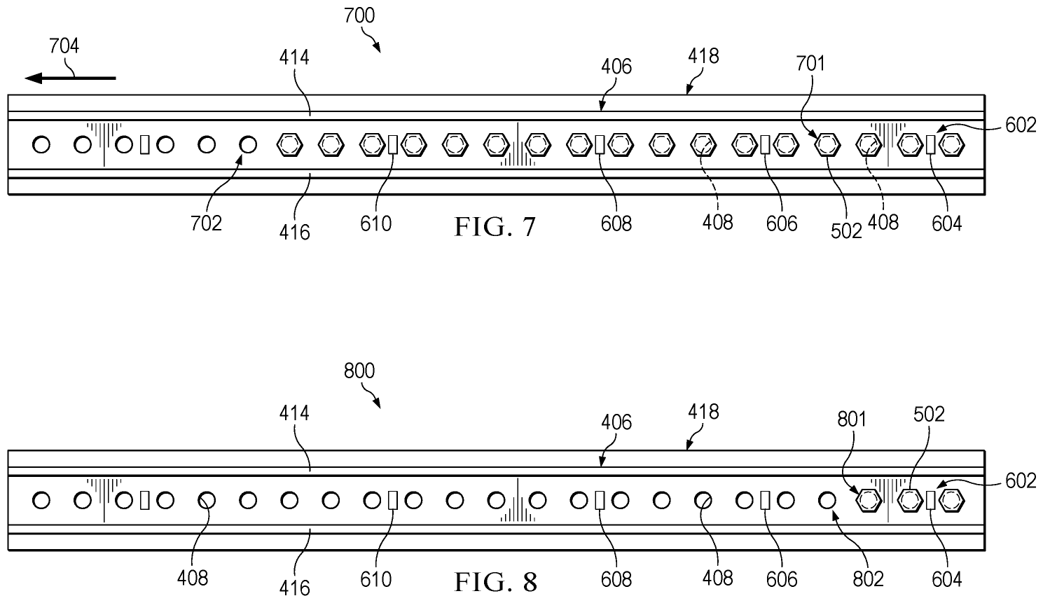

Turning now to FIG. 7, an illustration of a front view of single row joint testing equipment is depicted in accordance with an illustrative embodiment. In view 700 some of first plurality of holes 408 are empty. In view 700, the fasteners 701 depicted in FIG. 7 have a lower quantity of fasteners than fasteners 502 of FIGS. 5 and 6. In some illustrative examples, fasteners have been removed from fasteners 502 of FIGS. 5 and 6, leaving fasteners 701.

In view 700, hole 702 is the first hole in direction 704 that does not contain a fastener. Each hole of first plurality of holes 408 after hole 702 in direction 704 is also empty. In view 700, strain gauge 604, strain gauge 606, strain gauge 608, and strain gauge 610 will produce relevant strain measurements during testing.

By adjusting the number of fasteners inserted into single row joint testing equipment 400, the effective length of the fastened joint can be controlled. By adjusting the number of fasteners, many tests at temperature can be conducted on the single joint since it remains within elastic stress limits throughout testing.

Turning now to FIG. 8, an illustration of a front view of single row joint testing equipment is depicted in accordance with an illustrative embodiment. In view 800 the majority of first plurality of holes 408 are empty. In view 800, fasteners 801 depicted in FIG. 8 have a lower quantity of fasteners than fasteners 502 of FIGS. 5 and 6. In some illustrative examples, fasteners have been removed from fasteners 701 in FIG. 7, leaving fasteners 801.

In view 800, hole 802 is the first hole in direction 704 that does not contain a fastener. Each hole of first plurality of holes 408 after hole 802 in direction 704 is also empty. In view 700, only strain gauge 604 will produce relevant strain measurements during testing.

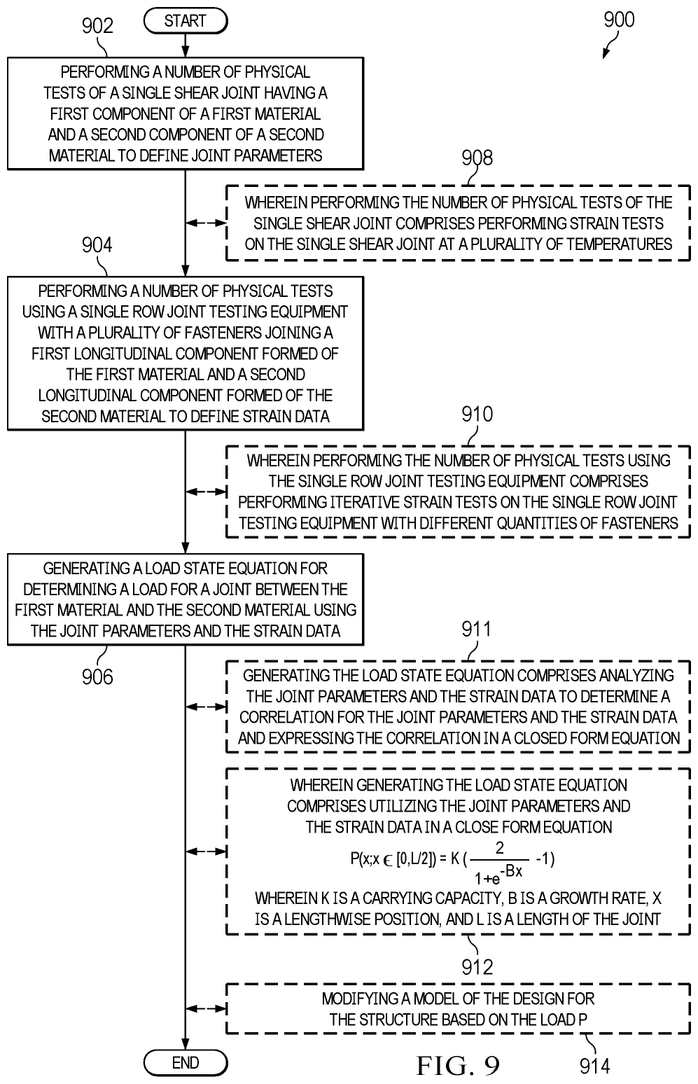

Turning now to FIG. 9, a flowchart of a method of designing a structure based on joint behaviors is depicted in accordance with an illustrative embodiment. Method 900 can be used to design a component of aircraft 100 of FIG. 1. Method 900 can be implemented in design environment 200 of FIG. 2 to perform at least one of single fastener testing 210 or multiple fastener testing 212. Method 900 can be implemented using single shear joint 300 of FIG. 3. Method 900 can be implemented using single row joint testing equipment 400 of FIGS. 4-8.

Method 900 can be used to design a structure such as structure 202 of FIG. 2. Method 900 performs a number of physical tests of a single shear joint having a first component of a first material and a second component of a second material to define joint parameters (operation 902). Method 900 performs a number of physical tests using a single row joint testing equipment with a plurality of fasteners joining a first longitudinal component formed of the first material and a second longitudinal component formed of the second material to define strain data (operation 904). Method 900 generates a load state equation for determining a load for a joint between the first material and the second material using the joint parameters and the strain data (operation 906). Afterwards, method 900 terminates.

In some illustrative examples, performing the number of physical tests of the single shear joint comprises performing strain tests on the single shear joint at a plurality of temperatures (operation 908). In some illustrative examples, performing the number of physical tests using the single row joint testing equipment comprises performing iterative strain tests on the single row joint testing equipment with different quantities of fasteners (operation 910). In some illustrative examples, generating the load state equation comprises analyzing the joint parameters and the strain data to determine a correlation for the joint parameters and the strain data and expressing the correlation in a closed form equation (operation 911).

In some illustrative examples, the load state equation takes the form of

$$P ( x ; x ∈ [ 0 , \frac{L}{2} ] ) = K ( \frac{2}{1 + {e}^{- B x}} - 1 ) ,$$

wherein K is a carrying capacity, B is a growth rate, X is a lengthwise position, and L is a length of the joint (operation 912). In some illustrative examples, method 900 modifies a model of the design for the structure based on the load P (operation 914).

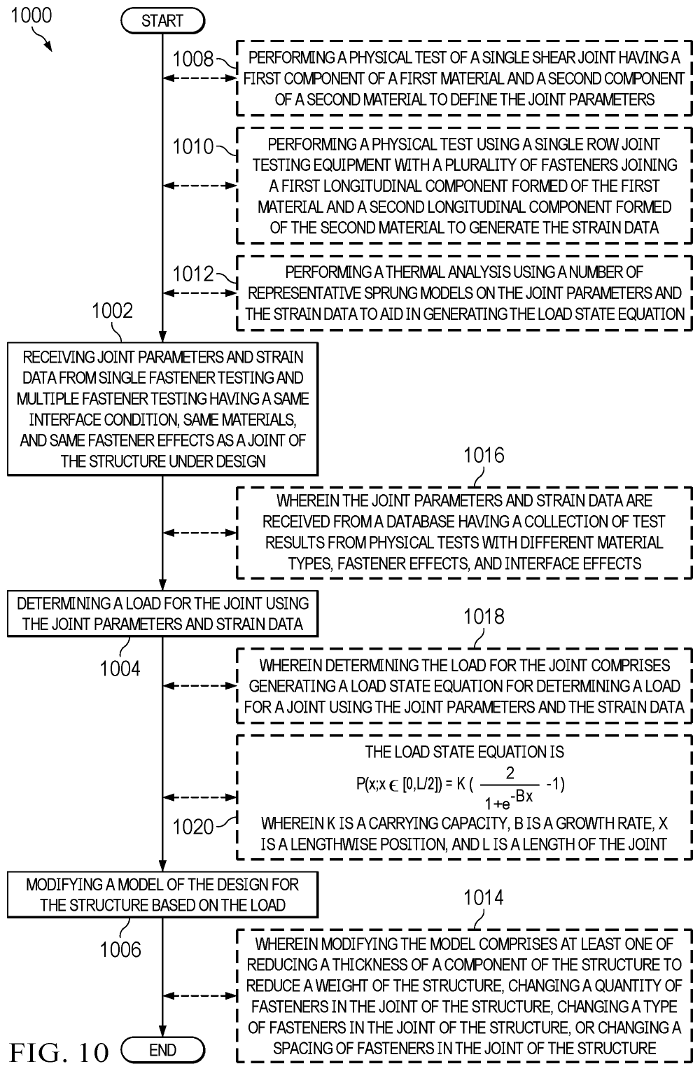

Turning now to FIG. 10, a flowchart of a method of designing a structure based on joint behaviors is depicted in accordance with an illustrative embodiment. Method 1000 can be used to design a component of aircraft 100 of FIG. 1. Method 1000 can be implemented in design environment 200 of FIG. 2 to perform multiple fastener testing 212. Method 1000 can be implemented using single shear joint 300 of FIG. 3. Method 1000 can be implemented using single row joint testing equipment 400 of FIGS. 4-8.

Method 1000 receives joint parameters and strain data from single fastener testing and multiple fastener testing having a same interface condition, same materials, and same fastener effects as a joint of the structure under design (operation 1002). Method 1000 determines a determining a load for the joint using the joint parameters and strain data (operation 1004). Method 1000 modifies a model of the design for the structure based on the load (operation 1006). Afterwards, method 1000 terminates.

In some illustrative examples, the joint parameters and strain data are received from a database having a collection of test results from physical tests with different material types, fastener effects, and interface effects (operation 1016).

In some illustrative examples, determining the load for the joint comprises generating a load state equation for determining a load for a joint using the joint parameters and the strain data (operation 1018).

In some illustrative examples, the load state equation is

$$P ( x ; x ∈ [ 0 , \frac{L}{2} ] ) = K ( \frac{2}{1 + {e}^{- B x}} - 1 ) ,$$

wherein K is a carrying capacity, B is a growth rate, X is a lengthwise position, and L is a length of the joint (operation 1020).

In some illustrative examples, method 1000 performs a physical test of a single shear joint having a first component of a first material and a second component of a second material to define the joint parameters (operation 1008). In some illustrative examples, method 1000 performs a physical test using a single row joint testing equipment with a plurality of fasteners joining a first longitudinal component formed of the first material and a second longitudinal component formed of the second material to generate the strain data (operation 1010).

In some illustrative examples, performing a thermal analysis using a number of representative sprung models on the joint parameters and the strain data to aid in generating the load state equation (operation 1012). In some illustrative examples, modifying the model comprises at least one of reducing a thickness of a component of the structure to reduce a weight of the structure, changing a quantity of fasteners in the joint of the structure, changing a type of fasteners in the joint of the structure, or changing a spacing of fasteners in the joint of the structure (operation 1014). In some illustrative examples, modifying the model comprises changing a clamp-up of fasteners in a joint.

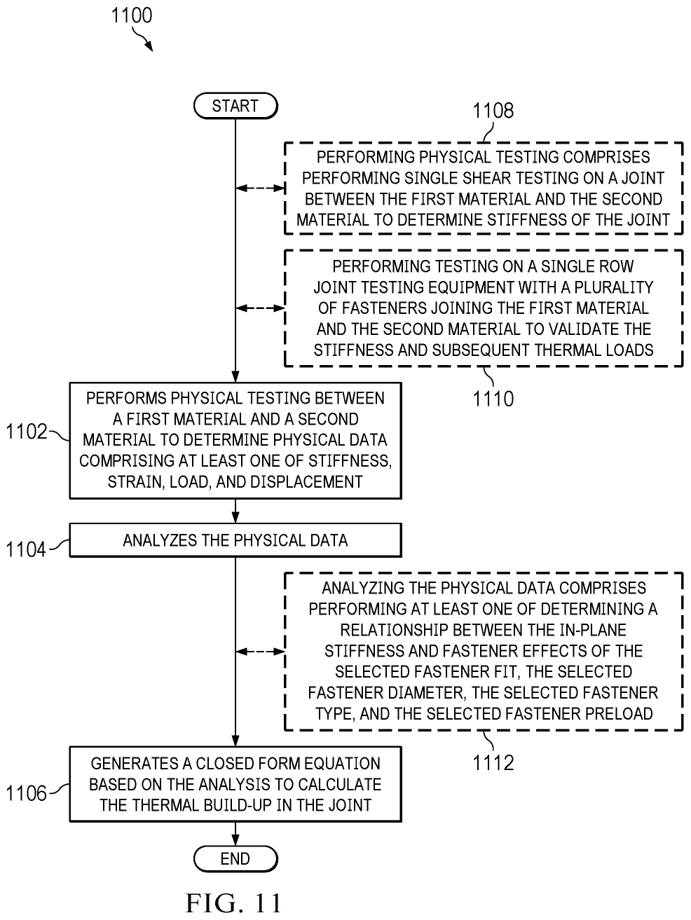

Turning now to FIG. 11, a flowchart of a method of analyzing thermal build-up in a joint is depicted in accordance with an illustrative embodiment. Method 1100 can be used to design a component of aircraft 100 of FIG. 1. Method 1100 can be implemented in design environment 200 of FIG. 2 to perform multiple fastener testing 212. Method 1100 can be implemented using single shear joint 300 of FIG. 3. Method 1100 can be implemented using single row joint testing equipment 400 of FIGS. 4-8.

Method 1100 performs physical testing between a first material and a second material to determine physical data comprising at least one of stiffness, strain, load, and displacement (operation 1102). Method 1100 analyzes the physical data (operation 1104). Method 1100 generates a closed form equation based on the analysis to calculate the thermal build-up in the joint (operation 1106).

In some illustrative examples, performing physical testing comprises performing single shear testing on a joint between the first material and the second material to determine stiffness of the joint (operation 1108), and performing testing on a single row joint testing equipment with a plurality of fasteners joining the first material and the second material to validate the stiffness and subsequent thermal loads (operation 1110). In some illustrative examples, analyzing the physical data comprises performing at least one of determining a relationship between the in-plane stiffness and fastener effects of the selected fastener fit, the selected fastener diameter, the selected fastener type, and the selected fastener preload (operation 1112).

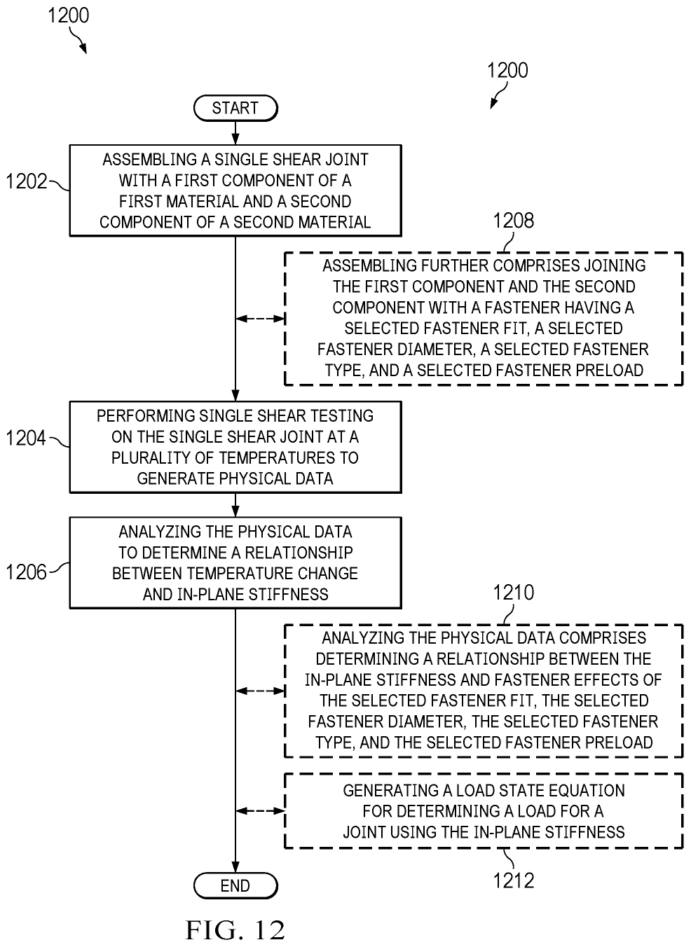

Turning now to FIG. 12, a flowchart of a method of determining a stiffness of a joint is depicted in accordance with an illustrative embodiment. Method 1200 can be used to design a component of aircraft 100 of FIG. 1. Method 1200 can be implemented in design environment 200 of FIG. 2 to perform single fastener testing 210. Method 1200 can be implemented using single shear joint 300 of FIG. 3.

Method 1200 assembles a single shear joint with a first component of a first material and a second component of a second material (operation 1202). Method 1200 performs single shear testing on the single shear joint at a plurality of temperatures to generate physical data (operation 1204). Method 1200 analyzes the physical data to determine a relationship between temperature change and in-plane stiffness (operation 1206). Afterwards, method 1200 terminates.

In some illustrative examples, assembling further comprises joining the first component and the second component with a fastener having a selected fastener fit, a selected fastener diameter, a selected fastener type, and a selected fastener preload (operation 1208). In some illustrative examples, analyzing the physical data comprises determining a relationship between the in-plane stiffness and fastener effects of the selected fastener fit, the selected fastener diameter, the selected fastener type, and the selected fastener preload (operation 1210). In some illustrative examples, method 1200 generates a load state equation for determining a load for a joint using the in-plane stiffness (operation 1212).

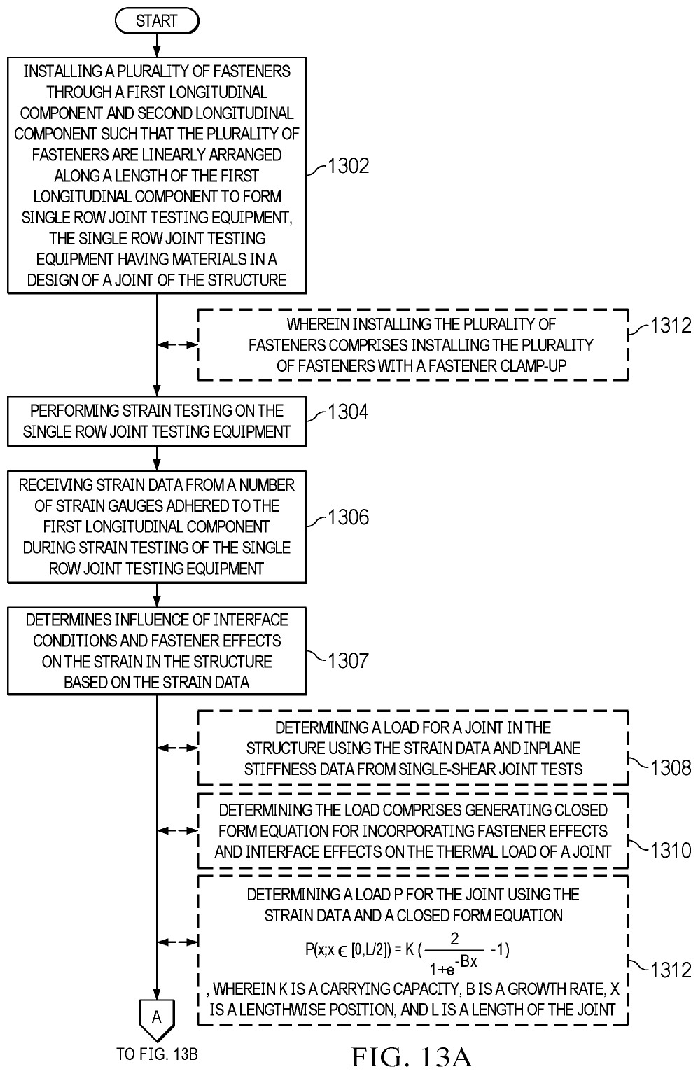

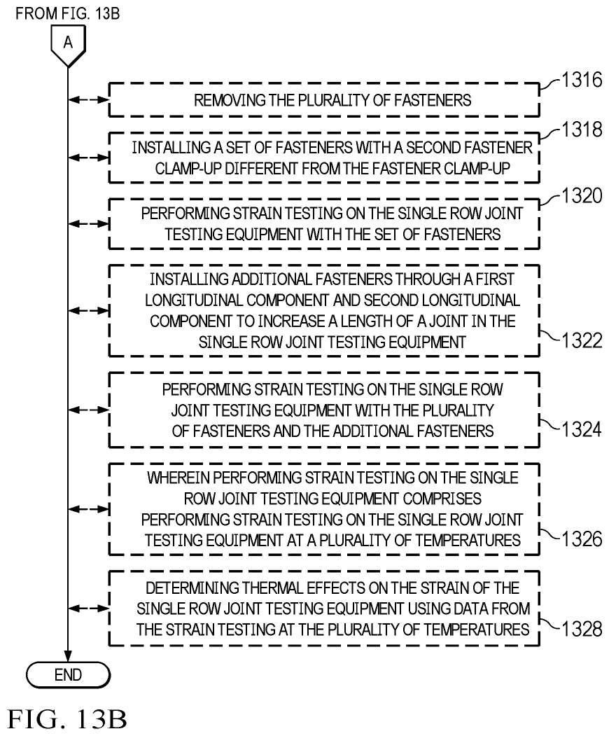

Turning now to FIGS. 13A and 13B, a flowchart of a method of designing a structure based on joint behaviors is depicted in accordance with an illustrative embodiment. Method 1300 can be used to design a component of aircraft 100 of FIG. 1. Method 1300 can be implemented in design environment 200 of FIG. 2 to perform multiple fastener testing 212. Method 1300 can be implemented using single row joint testing equipment 400 of FIGS. 4-8.

Method 1300 installs a plurality of fasteners through a first longitudinal component and second longitudinal component such that the plurality of fasteners are linearly arranged along a length of the first longitudinal component to form single row joint testing equipment, the single row joint testing equipment having materials in a design of a joint of the structure (operation 1302). Method 1300 performs strain testing on the single row joint testing equipment (operation 1304). Method 1300 receives strain data from a number of strain gauges adhered to the first longitudinal component during strain testing of the single row joint testing equipment (operation 1306). Method 1300 determines influence of interface conditions and fastener effects on the strain in the structure based on the strain data (operation 1307). Afterwards, method 1300 terminates.

In some illustrative examples, method 1300 determines a load for a joint in the structure using the strain data and in-plane stiffness data from single-shear joint tests (operation 1308). In some illustrative examples, determining the load comprises generating closed form equation for incorporating fastener effects and interface effects on the thermal load of a joint (operation 1310). In some illustrative examples, installing the plurality of fasteners comprises installing the plurality of fasteners with a fastener clamp-up (operation 1312). In some illustrative examples, method 1300 determines a load P for the joint using the strain data and a closed form equation

$$P ( x ; x ∈ [ 0 , \frac{L}{2} ] ) = K ( \frac{2}{1 + {e}^{- B x}} - 1 )$$

wherein K is a carrying capacity, B is a growth rate, X is a lengthwise position, and L is a length of the joint (operation 1314).

In some illustrative examples, method 1300 removes the plurality of fasteners (operation 1316). In some illustrative examples, method 1300 installs a set of fasteners with a second fastener clamp-up different from the fastener clamp-up (operation 1318). In some illustrative examples, method 1300 performs strain testing on the single row joint testing equipment with the set of fasteners (operation 1320).

In some illustrative examples, method 1300 installs additional fasteners through a first longitudinal component and second longitudinal component to increase a length of a joint in the single row joint testing equipment (operation 1322). In some illustrative examples, method 1300 performs strain testing on the single row joint testing equipment with the plurality of fasteners and the additional fasteners (operation 1324).

In some illustrative examples, performing strain testing on the single row joint testing equipment comprises performing strain testing on the single row joint testing equipment at a plurality of temperatures (operation 1326). In some illustrative examples, method 1300 determines thermal effects on the strain of the single row joint testing equipment using data from the strain testing at the plurality of temperatures (operation 1328).

As used herein, the phrase “at least one of,” when used with a list of items, means different combinations of one or more of the listed items may be used and only one of each item in the list may be needed. For example, “at least one of item A, item B, or item C” may include, without limitation, item A, item A and item B, or item B. This example also may include item A, item B, and item C or item B and item C. Of course, any combinations of these items may be present. In other examples, “at least one of” may be, for example, without limitation, two of item A; one of item B; and ten of item C; four of item B and seven of item C; or other suitable combinations. The item may be a particular object, thing, or a category. In other words, at least one of means any combination items and number of items may be used from the list but not all of the items in the list are required.

As used herein, “a number of,” when used with reference to items means one or more items.

The flowcharts and block diagrams in the different depicted embodiments illustrate the architecture, functionality, and operation of some possible implementations of apparatuses and methods in an illustrative embodiment. In this regard, each block in the flowcharts or block diagrams may represent at least one of a module, a segment, a function, or a portion of an operation or step.

In some alternative implementations of an illustrative embodiment, the function or functions noted in the blocks may occur out of the order noted in the figures. For example, in some cases, two blocks shown in succession may be executed substantially concurrently, or the blocks may sometimes be performed in the reverse order, depending upon the functionality involved. Also, other blocks may be added in addition to the illustrated blocks in a flowchart or block diagram. Some blocks may be optional. For example, operation 908 through operation 914 may be optional. As another example, operation 1008 through operation 1020 may be optional. For example, operation 1108 through operation 1114 may be optional.

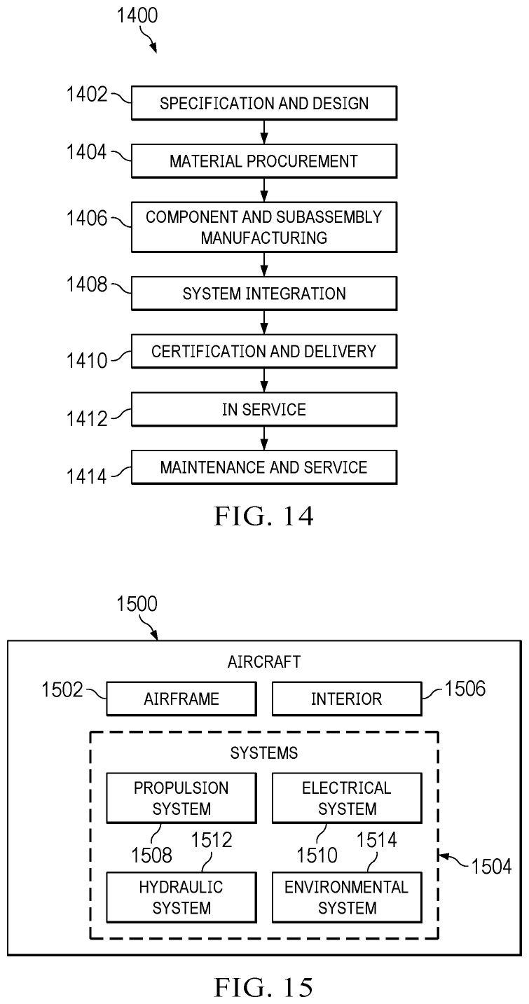

Illustrative embodiments of the present disclosure may be described in the context of aircraft manufacturing and service method 1400 as shown in FIG. 14 and aircraft 1500 as shown in FIG. 15. Turning first to FIG. 14, an illustration of an aircraft manufacturing and service method in a form of a block diagram is depicted in accordance with an illustrative embodiment. During pre-production, aircraft manufacturing and service method 1400 may include specification and design 1402 of aircraft 1500 in FIG. 15 and material procurement 1404.

During production, component and subassembly manufacturing 1406 and system integration 1408 of aircraft 1500 takes place. Thereafter, aircraft 1500 may go through certification and delivery 1410 in order to be placed in service 1412. While in service 1412 by a customer, aircraft 1500 is scheduled for routine maintenance and service 1414, which may include modification, reconfiguration, refurbishment, or other maintenance and service.

Each of the processes of aircraft manufacturing and service method 1400 may be performed or carried out by a system integrator, a third party, and/or an operator. In these examples, the operator may be a customer. For the purposes of this description, a system integrator may include, without limitation, any number of aircraft manufacturers and major-system subcontractors; a third party may include, without limitation, any number of vendors, subcontractors, and suppliers; and an operator may be an airline, a leasing company, a military entity, a service organization, and so on.

With reference now to FIG. 15, an illustration of an aircraft in a form of a block diagram is depicted in which an illustrative embodiment may be implemented. In this example, aircraft 1500 is produced by aircraft manufacturing and service method 1400 of FIG. 14 and may include airframe 1502 with plurality of systems 1504 and interior 1506. Examples of systems 1504 include one or more of propulsion system 1508, electrical system 1510, hydraulic system 1512, and environmental system 1514. Any number of other systems may be included.

Apparatuses and methods embodied herein may be employed during at least one of the stages of aircraft manufacturing and service method 1400. One or more illustrative embodiments may be manufactured or used during at least one of component and subassembly manufacturing 1406, system integration 1408, in service 1412, or maintenance and service 1414 of FIG. 14.

The illustrative examples improve vehicle analysis and design by improving the ability to accurately model thermally induced stresses in structural fastened joints consisting of materials with highly disparate coefficients of thermal expansion (CTE) (e.g., metallic and composites). The illustrative examples provide methods and apparatuses for determining and taking into account thermal loads in structural joints comprised of dissimilar materials.

The illustrative examples provide a new fastened joint analysis with strategically obtained test data to calibrate clamp-up responses and in-plane stiffness to provide rapid corrections to the standard approach of thermal loads analysis in structural fastened joints.

The illustrative examples consist of at least one of three aspects. The first aspect is the use of single shear fastened joint data generated from either test and/or analysis to identify and quantify the key joint parameters such as in-plane stiffness and quantify complex and non-obvious interface effects (e.g., fastener fit, friction, interface sealant, and fastener preload/clamp-up).

Because the legacy approaches ignore these behaviors and use undesirably conservative safety factors, the illustrative examples improve design of large structures. The illustrative examples provide quantitative information that can be used to correct, update, or verify the legacy approach without necessarily modifying the legacy models themselves-providing an innovative and cost-effective solution.

The second aspect of the illustrative examples provides a long single row (LSR) joint. The long single row (LSR) joint is a novel test joint relevant to spars or box beams within a structure. The long single row (LSR) joint provides the ability to characterize and quantify the effects of thermal strain development during environmental testing of joints of various lengths in a single manufactured joint.

The illustrative examples provide cost savings and cost avoidance. The illustrative examples enables weight reduction with little-to-no effect on analysis/design processes.

The use of single shear fastened joint data generated from either test and/or analysis is used to accurately identify and quantify the key joint parameters such as in-plane stiffness and quantify complex and non-obvious interface effects key to improving accuracy to real-world joint behavior: such as fastener fit, friction, interface sealant, and fastener preload/clam-up.

The illustrative examples generate data regarding the Temperature-dependent stiffness properties. The illustrative examples capture and quantify complex fastener/interface effects of physical joints. Afterwards, an analytical model of a single shear joint is generated.

The single row joint testing equipment was designed as a novel test joint relevant to spars or box beams within structure that provides the ability to characterize and quantify the effects of thermal strain development during environmental testing of joints of various lengths in a single manufactured joint.

This type of joint saves significant manufacturing cost to conduct thermal testing on fastened joints, demonstrates the excessive conservatism of standard vehicle-level analysis approaches, and provide remaining key parameters to describe necessary behaviors of a fastened joint that are lost in a welded FEM. Such a test is readily adapted to any potential materials, fastener types, fastener clamp-up conditions, fastener sizes/hole sizes, fastener tolerances, interface conditions (sealant, dry, friction, frictionless) etc. that may be utilized together in a vehicle and require analysis into in-plane stiffness, strains, and bearing loads and is straightforward to manufacture and test.

Additionally, the novel test article, the single row joint testing equipment, covers a wide range of relevant testing space at a reduced cost and captures the necessary mechanical behaviors to enable the closed form method for corrections. This all is readily applied during analysis phases of a vehicle and for each design iteration without compounding complexity at each iteration.

Either physical test results from the single shear joints and single row joint testing equipment or thermal analysis using smaller representative sprung models can be used to develop a closed form equation of a logistic function form to describe the stress and/or load state of the single row joint testing equipment over all possible joint lengths well. This function can in turn be used to find the bearing loads in the fasteners of the joint. This is amenable to developing design curves as part of the method for any given combination of materials to be fastened and subjected to thermal loads.

Therefore, either analytical or physical approaches for the single shear and single row joint testing equipment in combination provide the information to describe the accurate state of stress and load in a fastened joint subjected to thermal strains that has been shown to be less than or equal to the output of a welded FEM. Implementation of the method then provides a means for analysts to readily use output from a standard vehicle level FEM and find the appropriate knockdown using the informed closed form function for the given materials as a means to create thermo-mechanical design curves which are used to reduce conservatism and reduce weight in the vehicle.

The illustrative examples incorporate key mechanical behaviors (e.g., materials, fastener types, fastener clamp-up conditions, fastener sizes/hole sizes, fastener tolerances, fastener elasticity, interface conditions (sealant, dry, friction, frictionless) etc.) ignored by the legacy approaches and incorporates those behaviors more readily and rapidly than solutions deployed across the industry.

This enables reducing vehicle weight by more accurately capturing load states in a member subjected to thermally induced stresses while maintaining current modeling approaches without adding complexity and development time necessary of other existing solutions.

Enables weight reduction with little-to-no effect on analysis/design processes. The illustrative examples are aimed at modeling of joints made of dissimilar materials like composites and metal. This modeling can be used for fasteners and splice plates.

The description of the different illustrative embodiments has been presented for purposes of illustration and description, and is not intended to be exhaustive or limited to the embodiments in the form disclosed. Many modifications and variations will be apparent to those of ordinary skill in the art. Further, different illustrative embodiments may provide different features as compared to other illustrative embodiments. The embodiment or embodiments selected are chosen and described in order to best explain the principles of the embodiments, the practical application, and to enable others of ordinary skill in the art to understand the disclosure for various embodiments with various modifications as are suited to the particular use contemplated.

1. A method of designing a structure based on joint behaviors, the method comprising:
performing a number of physical tests of a single shear joint having a first component of a first material and a second component of a second material to define joint parameters;
performing a number of physical tests using a single row joint testing equipment with a plurality of fasteners joining a first longitudinal component formed of the first material and a second longitudinal component formed of the second material to define strain data; and
generating a load state equation for determining a load for a joint between the first material and the second material using the joint parameters and the strain data.

2. The method of claim 1, wherein performing the number of physical tests of the single shear joint comprises performing strain tests on the single shear joint at a plurality of temperatures.

3. The method of claim 1, wherein performing the number of physical tests using the single row joint testing equipment comprises performing iterative strain tests on the single row joint testing equipment with different quantities of fasteners.

4. The method of claim 1, wherein generating the load state equation comprises analyzing the joint parameters and the strain data to determine a correlation for the joint parameters and the strain data and expressing the correlation in a closed form equation taking into account fastener effects and interface effects.

5. The method of claim 4, wherein the load state equation is P(x;x∈[0,L/2])=K(2/(1+e\hat{ }(−Bx))−1), wherein K is a carrying capacity, B is a growth rate, X is a lengthwise position, and L is a length of the joint.

6. The method of claim 1 further comprising:
modifying a model of a design for the structure based on the load.

7. A method for verifying loads on a structure based on joint behaviors, the method comprising:
receiving joint parameters and strain data from single fastener testing and multiple fastener testing having a same interface condition, same materials, and same fastener effects as a joint of the structure under design;
determining a load for the joint using the joint parameters and strain data; and
modifying a model of a design for the structure based on the load.

8. The method of claim 7, wherein the joint parameters and strain data are received from a database having a collection of test results from physical tests with different material types, fastener effects, and interface effects.

9. The method of claim 7, wherein determining the load for the joint comprises:
generating a load state equation for determining a load for a joint using the joint parameters and the strain data.

10. (canceled)

11. The method of claim 7 further comprising:
performing a physical test of a single shear joint having a first component of a first material and a second component of a second material to define the joint parameters; and
performing a physical test using a single row joint testing equipment with a plurality of fasteners joining a first longitudinal component formed of the first material and a second longitudinal component formed of the second material to generate the strain data.

12. The method of claim 9 further comprising:
performing a thermal analysis using a number of representative sprung models on the joint parameters and the strain data to aid in generating the load state equation.

13. The method of claim 7, wherein modifying the model comprises at least one of reducing a thickness of a component of the structure to reduce a weight of the structure, changing a quantity of fasteners in the joint of the structure, changing a type of fasteners in the joint of the structure, or changing a spacing of fasteners in the joint of the structure.

14. A method to analyze thermal build-up in a joint comprising:
performing physical testing between a first material and a second material to determine physical data comprising at least one of stiffness, strain, load, and displacement;
analyzing the physical data; and
generating a closed form equation based on the analysis to calculate the thermal build-up in the joint.

15. The method of claim 14, wherein performing physical testing comprises:
performing single shear testing on a joint between the first material and the second material to determine stiffness of the joint; and
performing testing on a single row joint testing equipment with a plurality of fasteners joining the first material and the second material to validate the stiffness and subsequent thermal loads.

16. The method of claim 14, wherein analyzing the physical data comprises performing at least one of determining a relationship between in-plane stiffness and fastener effects of a selected fastener fit, a selected fastener diameter, a selected fastener type, and a selected fastener preload.

17. A method of determining a stiffness of a joint comprising:
assembling a single shear joint with a first component of a first material and a second component of a second material;
performing single shear testing on the single shear joint at a plurality of temperatures to generate physical data; and
analyzing the physical data to determine a relationship between temperature change and in-plane stiffness.

18. The method of claim 17, wherein assembling further comprises joining the first component and the second component with a fastener having a selected fastener fit, a selected fastener diameter, a selected fastener type, and a selected fastener preload.

19. The method of claim 18, wherein analyzing the physical data comprises determining a relationship between the in-plane stiffness and fastener effects of the selected fastener fit, the selected fastener diameter, the selected fastener type, and the selected fastener preload.

20. The method of claim 19 further comprising:
generating a load state equation for determining a load for a joint using the in-plane stiffness.

21. A method of designing a structure based on joint behaviors, the method comprising:
installing a plurality of fasteners through a first longitudinal component and second longitudinal component such that the plurality of fasteners are linearly arranged along a length of the first longitudinal component to form single row joint testing equipment, the single row joint testing equipment having materials in a design of a joint of the structure;
performing strain testing on the single row joint testing equipment;
receiving strain data from a number of strain gauges adhered to the first longitudinal component during strain testing of the single row joint testing equipment; and
determining influence of interface conditions and fastener effects on the strain in the structure based on the strain data.

22. The method of claim 21 further comprising:
determining a load for a joint in the structure using the strain data and in-plane stiffness data from single-shear joint tests.

23.-24. (canceled)

25. The method of claim 21, wherein installing the plurality of fasteners comprises installing the plurality of fasteners with a fastener clamp-up.

26. The method of claim 25 further comprising:
removing the plurality of fasteners;
installing a set of fasteners with a second fastener clamp-up different from the fastener clamp-up; and
performing strain testing on the single row joint testing equipment with the set of fasteners.

27. The method of claim 21 further comprising:
installing additional fasteners through a first longitudinal component and second longitudinal component to increase a length of a joint in the single row joint testing equipment; and
performing strain testing on the single row joint testing equipment with the plurality of fasteners and the additional fasteners.

28.-29. (canceled)

30. A single row joint testing equipment comprising:
a first longitudinal component having a first testing face with a first plurality of holes extending through the first testing face and linearly arranged along a length of the first longitudinal component;
a plurality of strain gauges connected to measuring face of the first longitudinal component opposite the first testing face; and
a second longitudinal component with a second testing face with a second plurality of holes extending through the second testing face and linearly arranged, wherein the second plurality of holes have the same spacing and diameter as the first plurality of holes, the second testing face configured to contact the first testing face.

31.-38. (canceled)
